(19) United States
(12) Patent Application Publication
(10) Pub. No.: US 2021/0175330 A1
(43) Pub. Date: Jun. 10, 2021

(54) SEMICONDUCTOR DEVICE, MANUFACTURING METHOD THEREOF, AND AMPLIFIER

(71) Applicant: FUJITSU LIMITED, Kawasaki-shi (JP)

(72) Inventor: Kozo Makiyama, Kawasaki (JP)

(73) Assignee: FUJITSU LIMITED, Kawasaki-shi (JP)

(21) Appl. No.: 17/078,139

(22) Filed: Oct. 23, 2020

(30) Foreign Application Priority Data
Dec. 4, 2019 (JP) 2019-219676

(51) Int. Cl. H01L 29/08; H01L 29/786; H01L 29/40; H01L 29/778; H01L 29/66; H01L 21/02

(52) U.S. Cl. CPC H01L 29/0847; H01L 29/7869; H01L 21/02274; H01L 29/7787; H01L 29/66462; H01L 29/402

(57) ABSTRACT

A semiconductor device includes a first semiconductor layer formed of a nitride semiconductor over a substrate; a second semiconductor layer formed of a nitride semiconductor over the first semiconductor layer; a gate electrode formed over the second semiconductor layer; a source electrode and a drain electrode formed over the first semiconductor layer or the second semiconductor layer; a first region of an insulative film that is formed between the gate electrode and the source electrode over the second semiconductor layer, and contains positive charges; and a second region of the insulative film that is formed between the gate electrode and the drain electrode over the second semiconductor layer, and contains negative charges.

### CROSS-REPERENCE TO RELATED APPLICATIONS

The present application is based upon and claims the benefit of priority of the prior Japanese Priority Application No. 2019-219676 filed on Dec. 4, 2019, the entire contents of which are hereby incorporated by reference.

### FIELD

The disclosures herein generally relate to a semiconductor device, a manufacturing method thereof, and an amplifier.

### BACKGROUND

Nitride semiconductors such as GaN, AlN,4 and InN, or mixed crystals of these materials have wide band gaps, and are used as high-output electronic devices, short-wavelength light emitting devices, and the like. For example, GaN, which is a nitride semiconductor, has a band gap of 3.4 eV, which is greater than the band gap of 1.1 eV of Si and the band gap of 1.4 eV of GaAs.

To be used as high-output devices, technologies relating to field-effect transistors (PET), especially, high electron mobility transistors (HBMT), have been developed (see, for example. Patent Document 1). A HBMT that uses a nitride semiconductor is used for a high-output, high-efficiency amplifier, a high-power switching device, or the like. Specifically, in a HBMT that uses AlGaN in an electron supply layer (a barrier layer, e.g., a layer formed of a material that has smaller electron affinity and a greater band gap than the electron transit layer) and GaN in an electron transit layer, piezoelectric polarization or the like is generated in AlGaN due to distortion caused by different lattice constants between AlGaN and GaN, and high-density 2DEG (Two-Dimensional Electron Gas) is generated. These material systems can operate at a high voltage, and can be used for high-efficiency switching element, a high-voltage endurance electric power device for electric vehicles and the like.

Among ultra-high-frequency devices using nitride semiconductors, in order to implement a higher output of the device, some devices use an electron supply layer formed of InAlN or InAlGaN that have high spontaneous polarization, instead of AlGaN. In the case of using InAlN or XnAXGaN for the electron supply layer, even though the layer is thin, it is possible to induce highly concentrated two-dimensional electron gas, and hence, it has attracted attention as a material having both a high-power characteristic and a high-frequency characteristic.

### RELATED-ART DOCUMENTS

### Patent Documents

Patent Document 1 Japanese Laid-open Patent Publication No. 2002-359256
Patent Document 2 Japanese Laid-open Patent Publication No. 2005-175376
Patent Document 3 Japanese Laid-open Patent Publication No. 2014-36212

Meanwhile, in a HMT using nitride semiconductors as described above, an attempt to increase the drain current tends to decrease the voltage endurance, and an attempt to increase the voltage endurance tends to decrease the drain current.

### SUMMARY

According to one aspect of the present embodiments, a semiconductor device includes a first semiconductor layer formed of a nitride semiconductor over a substrate; a second semiconductor layer formed of a nitride semiconductor over the first semiconductor layer; a gate electrode formed over the second semiconductor layer; a source electrode and a drain electrode formed over the first semiconductor layer or the second semiconductor layer; a first region of an insulative film that is formed between the gate electrode and the source electrode over the second semiconductor layer, and contains positive charges; and a second region of the insulative film that is formed between the gate electrode and the drain electrode over the second semiconductor layer, and contains negative charges.

The object and advantages of the embodiment will be realized and attained by means of the elements and combinations particularly pointed out in the claims. It is to be understood that both the foregoing general description and the following detailed description are exemplary and explanatory and are not: restrictive of the invention as claimed.

### BRIEF DESCRIPTION OF DRAWINGS

FIG. 1 is a structural diagram of a semiconductor device using nitride semiconductors;

FIG. 2 is an explanatory diagram of a semiconductor device using nitride semiconductors;

FIG. 3 is a structural diagram of a semiconductor device according to a first embodiment;

FIG. 4 is an explanatory diagram of a semiconductor device according to the first embodiment;

FIG. 5 is an explanatory diagram of the voltage endurance of a semiconductor device according to the first embodiment;

FIG. 6 is a structural diagram of a sample 6A in which nitride semiconductor layers are formed over a substrate;

FIG. 7 is a structural diagram of a sample 7A in which nitride semiconductor layers and a nitride silicon film are formed over a substrate;

FIG. 8 is an explanatory diagram of the sheetresistance in the sample 7A;

FIG. 9 is an explanatory diagram of the sheet resistance in the sample 7A to which heat treatment has been applied;

FIG. 10 is a process view (1) illustrating a manufacturing method of a semiconductor device according to the first embodiment;

FIG. 11 is a process view (2) illustrating the manufacturing method of the semiconductor device according to the first embodiment;

FIG. 12 is a process view (3) illustrating the manufacturing method of the semiconductor device according to the first embodiment;

FIG. 13 is a process view (4) illustrating the manufacturing method of the semiconductor device according to the first embodiment;

FIG. 14 is a process view (5) illustrating the manufacturing method of the semiconductor device according to the firet embodiment;

FIG. 15 is a process view (6) illustrating the manufacturing method of the semiconductor device according to the first embodiment;

FIG. 16 is a process view (7) illustrating the manufacturing method of the semiconductor device according to the first embodiment;

FIG. 17 is a process view (8) illustrating the manufacturing method of the semiconductor device according to the first, embodaiment;

FIG. 18 is a process view (9) illustrating the manufacturing method of the semiconductor device according to the first embodiment;

FIG. 19 is a process view (10) illustrating the manufacturing method of the semiconductor device according to the first embodiment;

FIG. 20 is a process view (11) illustrating the manufacturing method of the semiconductor device according to the first embodiment;

FIG. 21 is a process view (12) illustrating the manufacturing method of the semiconductor device according to the first embodiment;

FIG. 22 is a process view (13) illustrating the manufacturing method of the semiconductor device according to the first, embodiment;

FIG. 23 is an explanatory diagram (1) of a manufacturing method of a modified example 1 of a semiconductor device according to the first embodiment;

FIG. 24 is an explanatory diagram (2) of the manufacturing method of the modified example 1 of the semiconductor device according to the first embodiment;

FIG. 25 is an explanatory diagram (3) of the manufacturing method of the modified example 1 of the semiconductor device according to the first embodiment;

FIG. 26 is a structural diagram of a modified example 2 of a semiconductor device according to the first embodiment;

FIG. 27 is a structural diagram of a semiconductor device according to a second embodiment;

FIG. 28 is an explanatory diagram of a semiconductor device according to the second embodiment;

FIG. 29 is an explanatory diagram of the voltage endurance of a semiconductor device according to the second embodiment;

FIG. 30 is a process view (1) illustrating a manufacturing method of a semiconductor device according to the second embodiment;

FIG. 31 is a process view (2) illustrating the manufacturing method of the semiconductor device according to the second embodiment;

FIG. 32 is a process view (3) illustrating the manufacturing method of the semiconductor device according to the second embodiment;

FIG. 33 is a process view (4) illustrating the manufacturing method of the semiconductor device according to the second embodiment;

FIG. 34 is a process view (5) illustrating the manufacturing method of the semiconductor device according to the second embodiment;

FIG. 35 is a process view (6) illustrating the manufacturing method of the semiconductor device according to the second embodiment;

FIG. 36 is a process view (7) illustrating the manufacturing method of the semiconductor device according to the second embodiment;

FIG. 37 is a process view (8) illustrating the manufacturing method of the semiconductor device according to the second embodiment;

FIG. 38 is a process view (9) illustrating the manufacturing method of the semiconductor device according to the second embodiment;

FIG. 39 is a process view (10) illustrating the manufacturing method of the semiconductor device according to the second embodiment;

FIG. 40 is a process view (11) illustrating the manufacturing method of the semiconductor device according to the second embodiment;

FIG. 41 is a process view (12) illustrating the manufacturing method of the semiconductor device according to the second embodiment;

FIG. 42 is a process view (13) illustrating the manufacturing method of the semiconductor device according to the second embodiment;

FIG. 43 is a process view (14) illustrating the manufacturing method of the semiconductor device according to the second embodiment;

FIG. 44 is a process view (15) illustrating the manufacturing method of the semiconductor device according to the second embodiment;

FIG. 45 is an explanatory diagram (1) of a manufacturing method of a modified example of a semiconductor device according to the second embodiment;

FIG. 46 is an explanatory diagram (2) of the manufacturing method of the modified example of the semiconductor device according to the second embodiment;

FIG. 47 is an explanatory diagram (3) of the manufacturing method of the modified example of the semiconductor device according to the second embodiment;

FIG. 48 is a structural diagram of a semiconductor device according to a third embodiment;

FIG. 49 is an explanatory diagram of a semiconductor device according to the third embodiment;

FIG. 50 is an explanatory diagram of a semiconductor device according to a fourth embodiment;

FIG. 51 is a circuit diagram of a PPC circuit according to the fourth embodiment;

FIG. 52 is a circuit diagram of a power source device according to the fourth embodiment; and

FIG. 53 is a structural diagram of a high-frequency amplifier according to the fourth embodiment.

### DESCRIPTION OF EMBODIMENTS

In the following, embodiments of the present invention will be described with reference to the drawings. Note that the same numerical codes are assigned to the same members, and their description may be omitted.

According to a disclosed semiconductor device, in a HEMT using nitride semiconductors, it is possible to improve the voltage endurance without significantly decreasing the drain current.

### First Embodiment

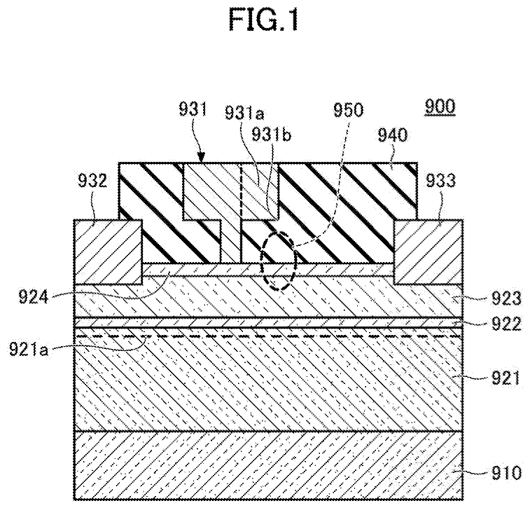

First, a HEMT as a semiconductor device using nitride semiconductors will be described based on FIG. 1. As illustrated in FIG. 1, this semiconductor device 900 includes a buffer layer (not illustrated), an electron transit layer 921, an intermediate layer 922, an electron supply layer 923, and a cap layer 924, which are layered over a substrate 910. The substrate 910 is formed of a semi-insulative SIC substrate. The electron transit layer 921 is formed of i-GaN, the intermediate layer 922 is formed of AlN, the electron supply layer 923 is formed of AlGaN, and the cap layer 924 is formed of GaN.

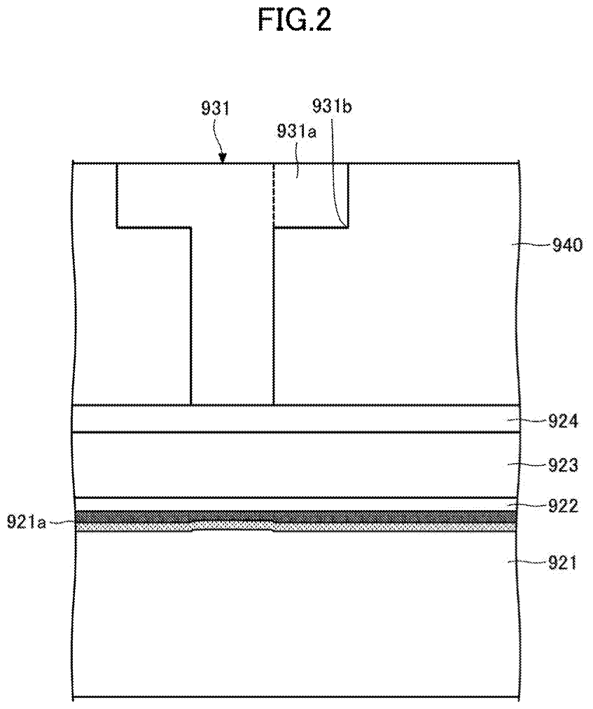

A gate electrode 931 is formed over the cap layer 924, and a source electrode 932 and a drain electrode 933 are formed over the electron supply layer 923. An insulative film 940 is formed over the cap layer 924 between the gate electrode 931 and the source electrode 932, and between the gate electrode 931 and the drain electrode 933, which is formed of silicon nitride or the like to serve as a protective film. In the semiconductor device illustrated in FIG. 1, Two-Dimensional Electron Gas (2DEG) 921a is generated in the vicinity of the interface between the electron transit layer 921 and the intermediate layer 922 in the electron transit layer 921. FIG. 2 illustrates a distribution of generated 2DEG 921a.

In the semiconductor device illustrated in FIG. 1, by increasing the concentration of the 2DEG 921a, it is possible to reduce the on resistance, and to increase the drain current. However, increasing the concentration of the 2DEG 921a reduces the voltage endurance due to concentration of the electric field. Specifically, in the case where the gate electrode 931 has a gate field plate 931a famed over the insulative film 940, the electric field concentrates in a region 950 surrounded by a dashed line directly beneath a terminal part 931b of the gate field plate 931a on the drain electrode 933-side. Therefore, even if a voltage to turn off is applied to the gate electrode 931, a current flows when the source-drain voltage becomes higher, and the device may be broken if the source-drain voltage becomes even higher. Note that in the present application, the voltage endurance is defined as a maximum value with respect to the current flowing between the source and the drain that is less than or equal to a predetermined value, for example, less than or equal to 5×10⁻⁵ A/mm, in the case of applying a voltage between the source and the drain in a state of applying a voltage that makes the gate electrode turned off.

Therefore, as a semiconductor device using nitride semiconductors, a device having high voltage endurance without decrease in the drain current has been desired.

### (Semiconductor Device)

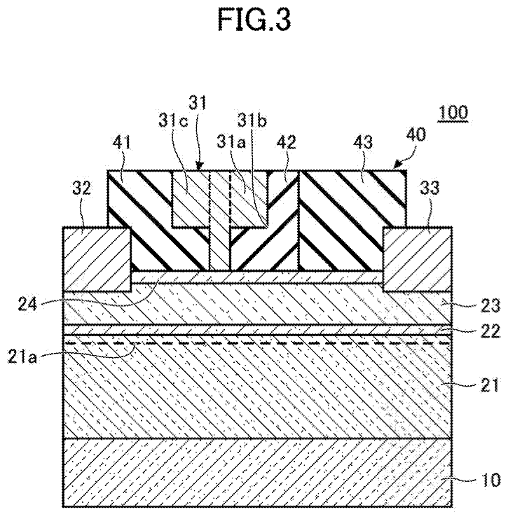

Next, a semiconductor device will be described according to a first embodiment based on FIG. 3. A semiconductor device 100 in the present embodiment includes a buffer layer (not illustrated), an electron transit layer 21, an intermediate layer 22, an electron supply layer 23, and a cap layer 24, which are layered over a substrate 10. The substrate 10 is formed of a semi-insulative SiC substrate. The electron transit layer 21 is formed of i-GaN to have a thickness of approximately 1 μm; the intermediate layer is formed of i-AlN to have a thickness of approximately 1 μm; arid the electron supply layer 23 is formed of AlGaN to have a thickness of approximately 10 nm. Also, the cap layer 24 is formed of GaN to have a thickness of approximately 5 nm. This structure generates 2DEG 21a in the electron transit layer 21 in the vicinity of the interface between the electron transit layer 21 and the intermediate layer 22. Note that in the present application, there are cases where the buffer layer (not illustrated), the electron transit layer 21, the intermediate layer 22, the electron supply layer 23, or the cap layer 24 is referred to as a nitride semiconductor layer. Also, there are cases where the electron transit layer 21 is referred to as a first semiconductor layer, and the electron supply layer 23 is referred to as a second semiconductor layer.

A gate electrode 31 is formed over the cap layer 24, and a source electrode 32 and a drain electrode 33 are formed over the electron supply layer 23. Over the cap layer 24 except for a region where the gate electrode 31 is formed, an insulative film 40 is formed of silicon nitride to serve as a protective film.

In the semiconductor device according to the present embodiment, gate field plates 31a and 31c are formed over the insulative film 40 as part of the gate electrode 31. In the gate electrode 31, the gate field plate 31a is formed on the drain electrode 33-side, and the gate field plate 31c is formed on the source electrode 32-side. In the insulative film 40, a first region 41 containing positive charges is formed on the source electrode 32-side of the gate electrode 31 including a region directly beneath the gate field plate 31c. Also, a second region 42 containing negative charges is formed on the drain electrode 33-side including a region directly beneath the gate field plate 31a. A third region 43 is formed on the drain electrode 33-side of the second region 42. The third region 43 may be formed of silicon nitride containing positive charges, or may be formed of silicon nitride in a stoichiometric state.

Therefore, the first region 41 of the insulative film 40 is formed on the source electrode 32-side relative to the gate electrode 31, and to include a region directly beneath the gate field plate 31c. The second region 42 of the insulative film 40 is formed on the drain electrode 33-side relative to the gate electrode 31 in a region directly beneath a terminal part 31b of the gate field plate 31a on the drain electrode 33-side and a vicinity of the region.

Meanwhile, although silicon nitride that forms the insulative film 40 is Si₃N₄ in a stoichiometric state, there are N-rich silicon nitride containing a greater amount of N, and Si-rich silicon nitride containing a greater amount of Si than Si₃N₄ in the stoichiometric state.

N-rich silicon nitride contains a greater amount of N than Si₃N₄ in the stoichiometric state, which causes it to be electron-excessive (due to a large number of Si holes), to contain negative charges, and to have a lower refractive index. Conversely, a silicon nitride film contains a greater amount of Si than Si₃N₄ in the stoichiometric state, which causes it to be electron-deficient (due to a large number of N holes), and to have a higher refractive index. Note that Si₃N₄ in the stoichiometric state is thought to have few charges in the film.

Therefore, the first region 41 and the second region 42 of the insulative film 40 are formed of silicon nitride, wherein the first region 41 is formed of silicon nitride containing positive charges, and the second region 42 is formed of silicon nitride containing negative charges.

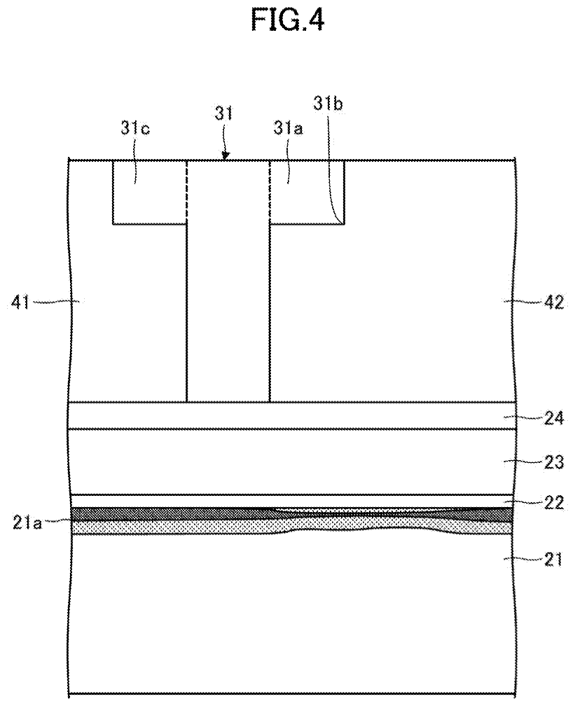

FIG. 4 illustrates a distribution of 2DEG 21a generated in the semiconductor device according to the present embodiment. As illustrated in FIG. 4, in the vicinity directly beneath the terminal part 31b of the gate field plate 31a of the gate electrode 31 on the drain electrode 33-side, the concentration of the 2DEG 21a is lower. In other words, the second region 42 of the insulative film 40 contains negative charges; therefore, the concentration of the 2DEG 21a generated in the electron transit layer 21 becomes lower, and the resistance of this part becomes higher. Therefore, the concentration of the electric field is alleviated directly beneath the terminal part 31b of the gate field plate 31a of the gate electrode 31 on the drain electrode 33-side, and the voltage endurance can be improved.

Also, the first region 41 of the insulative film 40 contains positive charges; therefore, the concentration of the 2DEG 21a generated in the electron transit layer 21 becomes higher, and the resistance of this part becomes lower, and the on-resistance becomes lower; therefore, the decrease in the drain current is suppressed.

In the present embodiment, silicon nitride that: forms the first region 41 and contains positive charges, has N/Si of approximately 1.063, a refractive index at a wavelength of 633 nm of approximately 2.25, and a charge density of positive charges of 2×1012 cm⁻² in the direction of the substrate surface. Also, silicon nitride that forms the second region 42 and contains negative charges, has N/Si of approximately 1.441, a refractive index at the wavelength of 633 nm of approximately 1.90, and a charge density of negative charges of 2×1012 cm⁻² in the direction of the substrate surface. Note that Si₃K₄ in the stoichiometric state has N/Si of approximately 1.333, a refractive index at the wavelength of 633 nm of approximately 2.0, and contains few positive charges or negative charges.

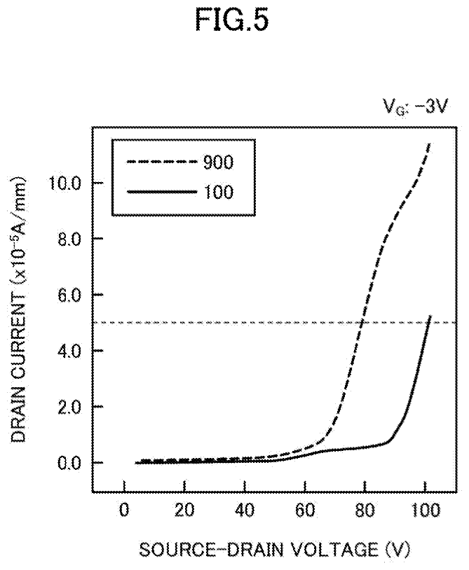

FIG. 5 illustrates a relationship between the source-drain voltage and the drain current in an off-state where −3 V is applied to the gate electrode in the semiconductor device 100 in the present embodiment illustrated in FIG. 3, and in the semiconductor device 900 illustrated in FIG. 1. In the case of assuming that the voltage endurance corresponds to a drain current of 5×10⁻⁵A/mm, the voltage endurance of the semiconductor device 900 illustrated in FIG. 1 is approximately 75 V, whereas the voltage endurance of the semiconductor device 100 in the present embodiment is approximately 100 V, which is higher than the device illustrated in FIG. 1.

### (Silicon Nitride)

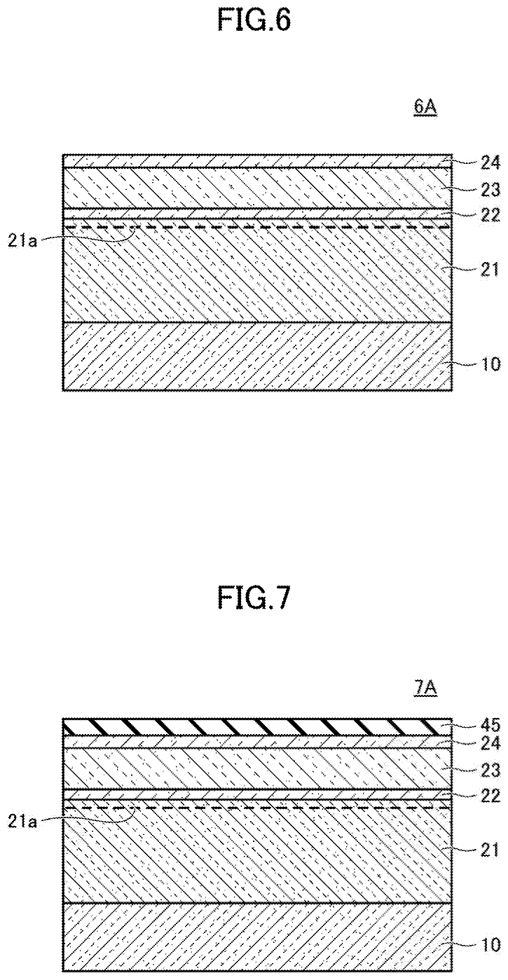

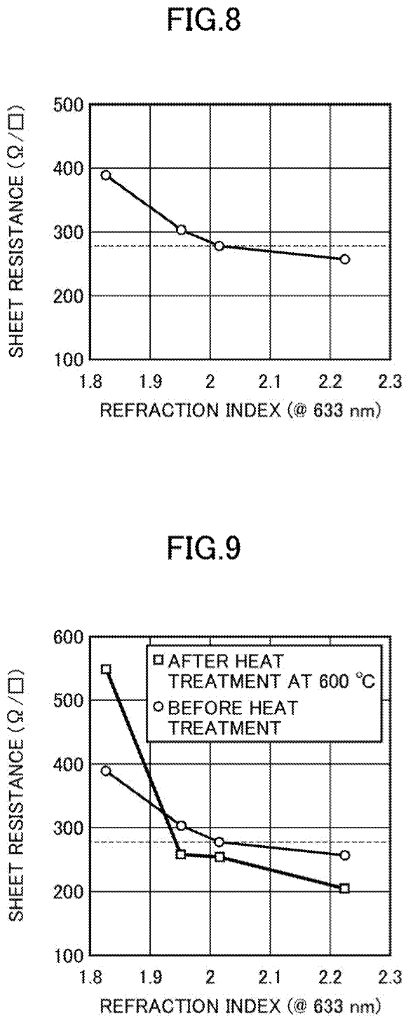

Next, the effects in the case of forming silicon nitride as an insulative film in the semiconductor device according to the present embodiment will be described in more detail based on FIGS. 6 to 8. FIG. 6 illustrates a structure of a sample 6A in which nitride semiconductor layers were formed in substantially the same way as in the semiconductor device according to the present embodiment. A buffer layer (not illustrated), an electron transit layer 21, an intermediate layer 22, an electron supply layer 21, and a cap layer 24 were sequentially formed over a substrate 10. The sheet resistance of the sample 6A illustrated in FIG. 6 was approximately 280 Ω/□. FIG. 7 illustrates a structure of a sample 7A in which a silicon nitride film 45 was formed over the cap layer 24 illustrated in FIG. 6; and FIG. 8 illustrates results of measurement of the sheet resistance of the sample 7A with silicon nitride films 45 having different values of N/Si.

In the case where the silicon nitride film 45 of the sample 7A was formed of Si₃N₄ in the stoichiometric stace having a refractive index of approximately 2.0 at the wavelength of 633 nm, the sheet resistance was approximately 280 Q/G as in the case of the sample 6A illustrated in FIG. 6. This is because positive charges or negative charges are not present in Si₃N₄ in the stoichiometric state; therefore, the 2DEG 21a is not affected, and hence, no change occurs in the sheet resistance.

Also, in the case where the silicon nitride film 45 of the sample 7A was formed of Si-rich silicon nitride having a refractive index of approximately 2.22 at the wavelength of 633 nm, the sheet resistance was approximatey 255 Ω/□, which was lower than the sheet resistance of Si₃N₄ in the stoichiometric state. This is because there were many positive charges in Si-rich silicon nitride relative to Si₃N₄ in the stoichiometric state; therefore, due to the effect of many positive charges, the concentration of the 2DEG 21a became higher and the sheet resistance became lower.

Also, in the case where the silicon nitride film 45 of the sample 7A was formed of N-rich silicon nitride having a refractive index of approximately 1.95 at the wavelength of 633 nm, the sheet resistance was approximately 300 Ω/□, which was higher than the sheet resistance of Si₃N₄ in the stoichiometric state. This is because there were many negative charges in N-rich silicon nitride relative to Si₃N₄ in the stoichiometric state; therefore, due to the effect of many negative charges, the concentration of the 2DEG 21a became lower and the sheet resistance became higher.

Also, in the case where the silicon nitride film 45 of the sample 7A was formed of N-rich silicon nitride having a refractive index of approximately 1.82 at the wavelength of 633 nm, the sheet resistance was approximately 390 Ω/□, which was even higher than in the case of silicon nitride having the refraction index of approximately 1.95. This is because there were more negative charges in the silicon nitride having the refraction index of approximately 1.82 than in the silicon nitride having the refraction index of approximately 1.95; therefore, it is considered that the concentration of the 2DEG 21a became even lower and the sheet resistance became higher.

Next, the effect of heat treatment applied to the sample 7A illustrated in FIG. 7 will be described based on FIG. 9. As illustrated in FIG. 9, in the case of Si₃N₄ in the stoichiometric state having a refractive index of approximately 2.0 at the wavelength of 633 nm, by applying heat treatment at a temperature of 600° C. for 1 hour, the sheet resistance decreased from approximately 280 Ω/□ to approximately 255 Ω/□.

Also, in the case of Si-rich silicon nitride having a refractive index of approximately 2.22 at the wavelength of 633 nm, by applying heat treatment at a temperature of 600° C. for 1 hour, the sheet resistance decreased from approximately 255 Ω/□ to approximately 200 Ω/□.

Also, in the case of N-rich silicon nitride having a refractive index of approximately 1.95 at the wavelength of 633 nm, by applying heat treatment at a temperature of 600° C. for 1 hour, the sheet resistance decreased from approximately 300 Ω/□ to approximately 260 Ω/□.

Also, in the case of N-rich silicon nitride having a refractive index of approximately 1.80 at the wavelength of 633 nm, by applying heat treatment at a temperature of 600° C. for 1 hour, the sheet resistance increased from approximately 390 Ω/□ to approximately 550 Ω/□.

Therefore, in the case of Si₃N₄ in the stoichiometric state and Si-rich silicon nitride, by applying heat treatment at a temperature of higher than or equal to 600° C. for 1 hour, the sheet resistance decreased. Also, in the case of N-rich silicon nitride, by applying heat treatment at a temperature of higher than or equal to 600° C. for 1 hour, the sheet resistance increased in silicon nitride containing more negative charges, and the sheet resistance decreased similarly to the stoichiometric state in silicon nitride containing fewer negative charges.

In the present embodiment, although the cases have been described in which the insulative film 40 is silicon nitride, the insulative film 40 may be nitride such as aluminum nitride, or oxide such as silicon oxide, aluminum oxide, hafnium oxide, magnesium oxide, or the like. In the case of aluminum nitride, by increasing the nitrogen component relative to AlN in a stoichiometric state, it is possible to obtain N-rich AlN containing negative charges, and by reducing the nitrogen component relative to the stoichiometric state, it is possible to obtain Al-rich AlN containing negative charges. Also, the same applies to oxides such as silicon oxide, aluminum oxide, hafnium oxide, magnesium oxide, and the like. In other words, by increasing the oxygen component relative to SiO₂, Al₂O₃, HfO, or MgO in a stoichiometric state, it is possible to obtain an O-rich material containing negative charges, and by reducing the oxygen component relative to the stoichiometric state, it is possible to obtain a material containing negative charges.

A silicon nitride film containing positive charges and a silicon nitride film containing negative charges can be deposited by plasma CVD (Chemical Vapor Deposition), sputtering, and the like. Note that a silicon nitride film deposited by plasma CVD contains hydrogen by 5% or greater.

Also, the semiconductor device according to the present embodiment may not have an intermediate layer 22 provided, or may not have a cap layer 24 provided. Also, the electron supply layer 23 may be formed of InAlN or InAlGaN instead of AlGaN.

### (Manufacturing Method of Semiconductor Device)

Next, a manufacturing method of the semiconductor device according to the present embodiment will be described based on FIGS. 10 to 22. Note that in process views in the following description, for the sake of convenience, the thickness, width and the like of each layer may be presented differently from those illustrated in FIG. 3 and the like; however, these do not affect the contents of the present inventive concept.

First, as illustrated in FIG. 10, a buffer layer (not illustrated), an electron transit layer 21, an intermediate layer 22, an electron supply layer 23, and a cap layer 24 are sequentially laminated and formed over a substrate 10 by epitaxial growth using MOVPE (Metal Organic Vapor Phase Epitaxy). The electron transit layer 21 is formed of i-GaN to have a thickness of approximately 1 μm; the intermediate layer is formed of i-AlN to have a thickness of approximately 1 μm; and the electron supply layer 23 is formed of AlGaN to have a thickness of approximately 10 nm. The cap layer 24 is formed of GaN to have a thickness of approximately 2 nm. This structure generates 2DEG 21a in the electron transit layer 21 in the vicinity of the interface between the electron transit layer 21 and the intermediate layer 22. Note that a semi-insulative SiC substrate is used for the substrate 10, and the buffer layer (not-illustrated) is formed of GaN, AlGaN, or the like.

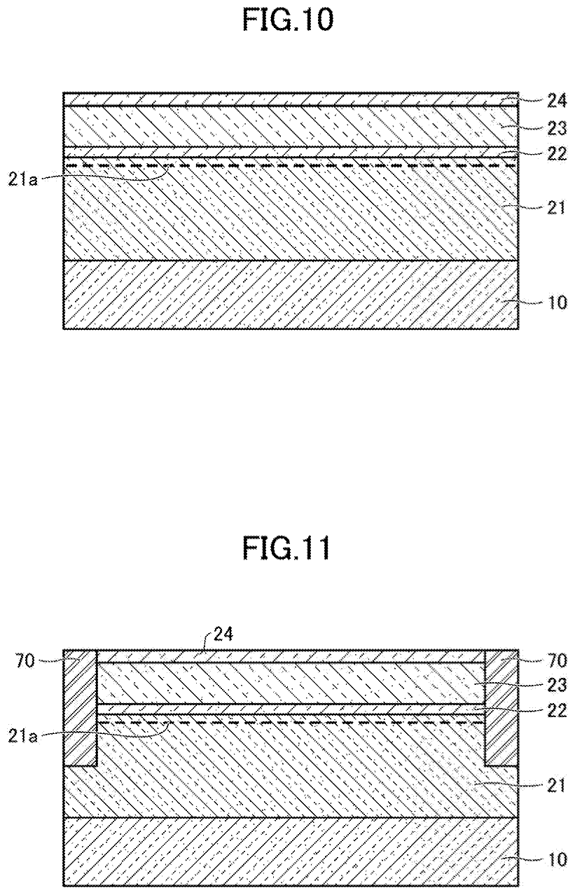

Next, as illustrated in FIG. 11, element-separating regions 70 are formed in the nitride semiconductor layers formed over the substrate 10. Specifically, by applying a photoresist onto the cap layer 24, which is then exposed by an exposure device and developed, a resist pattern (not illustrated) is formed to have openings in regions where the element-separating regions 70 are to be formed. After that, ions of Ar or the like are implanted into the nitride semiconductor layers in the openings of the resist pattern, to form the element-separating regions 70. After that, the resist pattern (not illustrated) is removed by an organic solvent or the like.

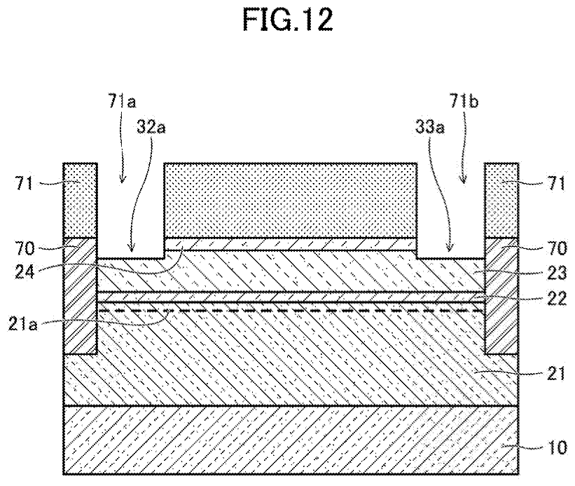

Next, as illustrated in FIG. 12, a resist pattern 71 having openings 71a and 71b is formed, and then, the nitride semiconductor layers are removed in regions where a source electrode 32 and a drain electrode 33 are to be formed, to form openings 32a and 33a. Specifically, by applying a photoresist onto the cap layer 24, which is then exposed by an exposure device and developed, the resist pattern 71 is formed to have the openings 71a and 7lb in the regions where the source electrode 32 and the drain electrode 33 are to be formed. After that, part of the cap layer 24 and the electron supply layer 23 is removed, by dry etching such as RIE (Reactive Ion Etching) that uses a chlorine-based gas as the etching gas. Thus, the openings 32a and 33a are formed in the regions where the source electrode 32 and the drain electrode 33 are to be formed.

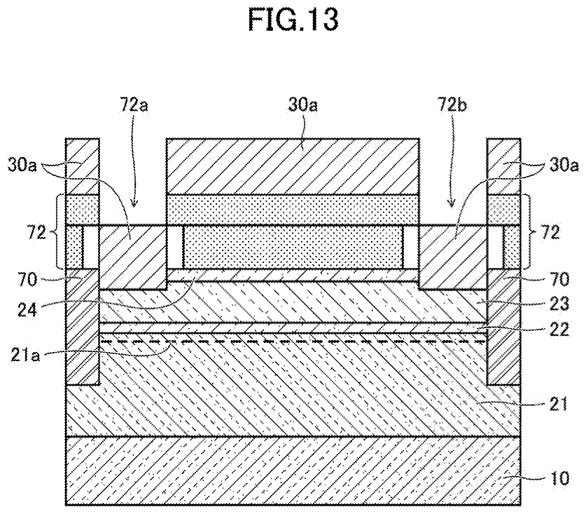

Next, as illustrated in FIG. 13, a resist pattern 72 is formed to have openings 72a and 72b to form the source electrode 32 and the drain electrode 33, and then, a multilayer metal film 30a is deposited to form the source electrode 32 and the drain electrode 33. Specifically, the resist pattern 71 on the cap layer 24 and the like is removed by an organic solvent or the like, and then, the photoresist is applied again onto the cap layer 24 and the like, exposed by the exposure device, and developed. Thus, a resist pattern 72 is formed to have the openings 72a and 72b in the regions where the source electrode 32 and the drain electrode 33 are to be formed. Specifically, by applying PMGI as a lower-layer resist to have a thickness of 500 nm by spin-coating, and applying i-line resist (PFI-32A8) as the upper-layer resist to have a thickness of 1 μm onto the lower-layer resist by spin-coating, which are then exposed, a resist shape having an eave structure suitable for a lift-off method is formed. After that, the multilayer metal film 30a is deposited to form the source electrode 32 and the drain electrode 33 by vacuum deposition. The multilayer metal film 30a is a laminated film in which a Ti film having a film thickness of 20 nm and an Al film having a film thickness of 200 nm are laminated sequentially.

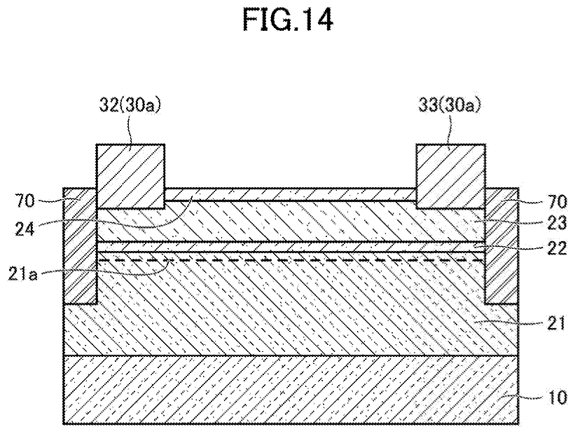

Next, as illustrated in FIG. 14, by immersing in an organic solvent or the like, the multilayer metal film 30a formed over the resist pattern 72 is removed together with the resist pattern 72 by lift-off. Thus, the gate electrode 31 is formed by the multilayer metal film 30a remaining in the openings 72a and 72b of the resist pattern 72. After that, heat treatment is applied at a temperature of 550° C. to 650° C., to establish an ohmic contact between the nitride semiconductor layers, and the source electrode 32 and the drain electrode 33.

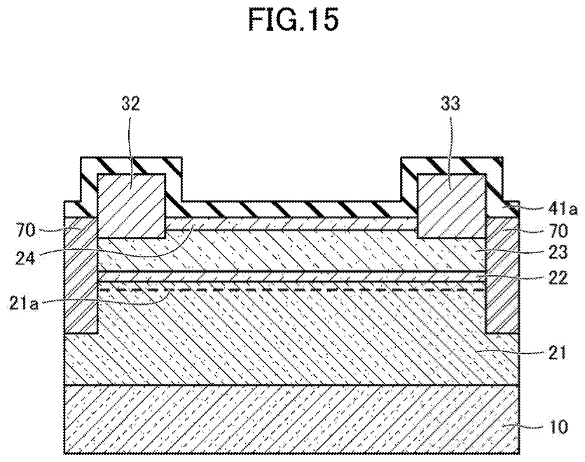

Next, as illustrated in FIG. 15, a positive-charge-containing film 41a is formed over the cap layer 24 and the like to form a first region 41 and a third region 43 of the insulative film 40. Specifically, the positive-charge-containing film 41a is formed by depositing an SiN film having a film thickness of approximately 20 nm by plasma CVD, using silane (SiH₄), ammonia (NH₃), or nitrogen (N₂) as the source gas. The deposit conditions when depositing the positive-charge-containing film 41a are: a flow rate of 3.9 sccm for silane; a flow rate of 200 sccm for nitrogen; a deposition pressure of 1 Torr; and an applied power of 50 W. By executing the deposition under these conditions, an Si-rich positive-charge-containing film 41a having a refractive index of 2.25 is formed.

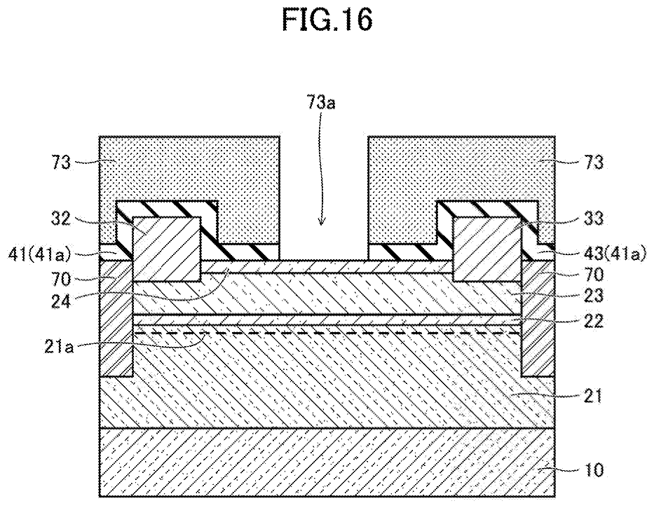

Next, as illustrated in FIG. 16, a resist pattern 73 having an opening 73a is formed over the positive-charge-containing film 41a, and then, the positive-charge-containing film 41a is removed in the opening 73a of the resist pattern 73, to expose the cap layer 24. Specifically, by applying a photoresist onto the positive-charge-containing film 41a, which is then exposed by an exposure device and developed, the resist pattern 73 having the opening 73a is formed. After that, by dry etching such as RIE, the positive-charge-containing film 41a is removed in the opening 73a of the resist pattern 73, to expose the cap layer 24. Thus, the remaining positive-charge-containing film 41a forms the first region 41 and the third region 43 that form the insulative film 40. After that, the photoresist pattern 73 is removed by an organic solvent or the like.

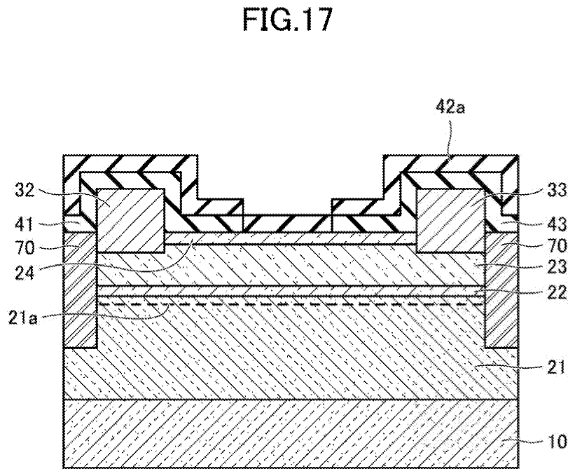

Next, as illustrated in FIG. 17, a negative-charge-containing film 42a is formed over the cap layer 24 and the like to form a second region 42 of the insulative film 40. Specifically, the negative-charge-containing film 42a is formed by depositing an SiN film having a film thickness of approximately 100 nm by plasma CVD, using silane, ammonia, or nitrogen as the source gas. The deposit conditions when depositing the regative-charge-containing film 42a are: a flow rate of 1.5 sccm for silane; a flow rate of 200 sccm for nitrogen; a deposition pressure of 1 Torr; and an applied power of 50 W. Thus, an N-rich, negative-charge-containing film 42a having a refractive index of 1.90 is formed. After that, heat treatment is applied at 600° C. for 1 minute.

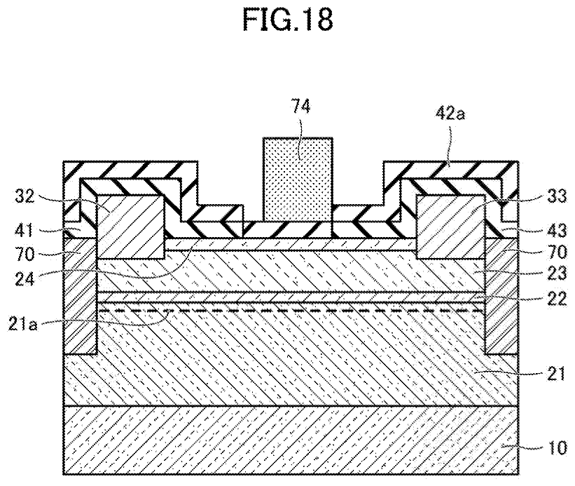

Next, as illustrated in FIG. 18, a resist pattern 74 is formed over the negative-charge-containing film 42a, in a region where the second region 42 of the insulative film 40 is to be formed. Specifically, by applying a photoresist onto the negative-charge-containing film 42a, which is then exposed by an exposure device and developed, the resist pattern 74 is formed over the region where the second region 42 is to be formed.

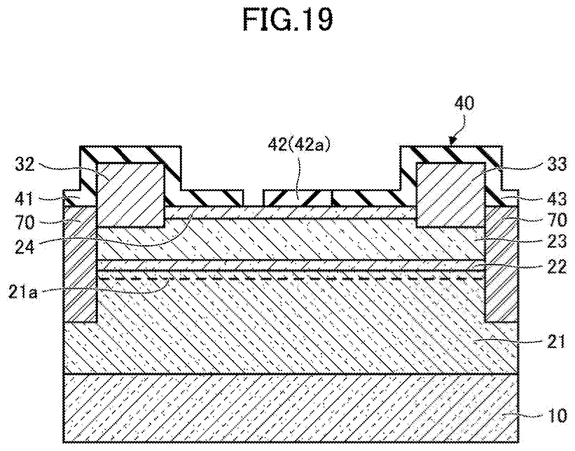

Next, as illustrated in FIG. 19, by removing the negative-charge-containing film 42a in a region where the resist pattern 74 is not formed by dry etching such as RIB, the second region 42 forming part of the insulative film 40 is formed by the remaining negacive-charge-concaining film 42a. Thus, the insulative film 40 is formed with the first region 41, the second region 42, and the third region 43. After that, the resist pattern 74 is removed by an organic solvent or the like.

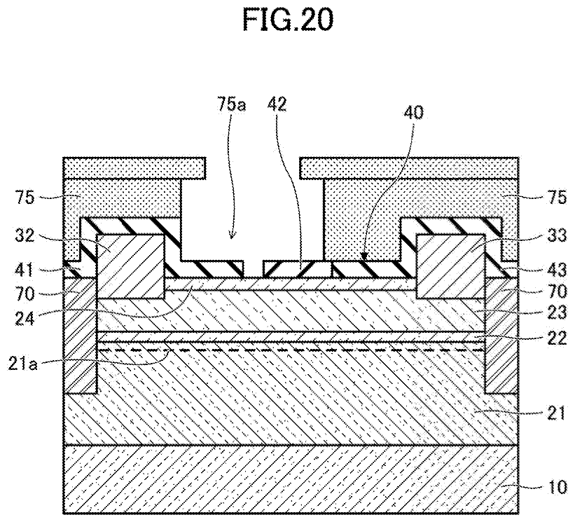

Next, as illustrated in FIG. 20, a resist pattern 75 is formed to have an opening 75a in a region where the gate electrode 31 is to be formed. This resist pattern 75 is formed with two layers of resist layers, and the opening is wider on the bottom side than on the opening side.

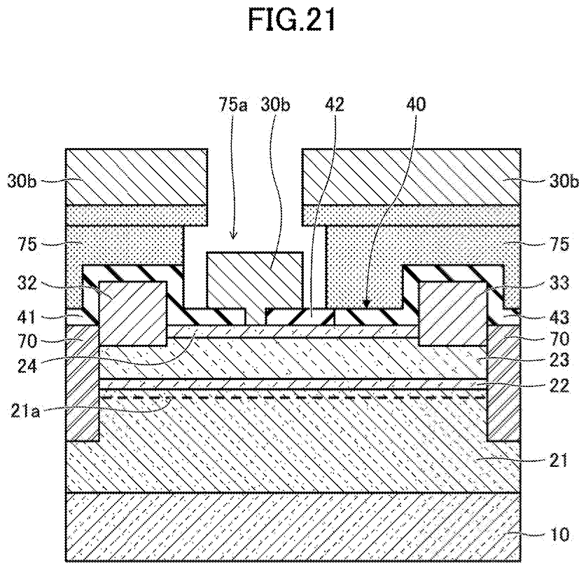

Next, as illustrated in FIG. 21, a multilayer metal film 30b to form a gate electrode 31 by vacuum deposition is deposited on the surface on which the resist pattern 75 is formed. The multilayer metal film 30b is a laminated film in which an Ni film having a film thickness of 10 nm and an Au film having a film thickness of 300 nm are laminated sequentially.

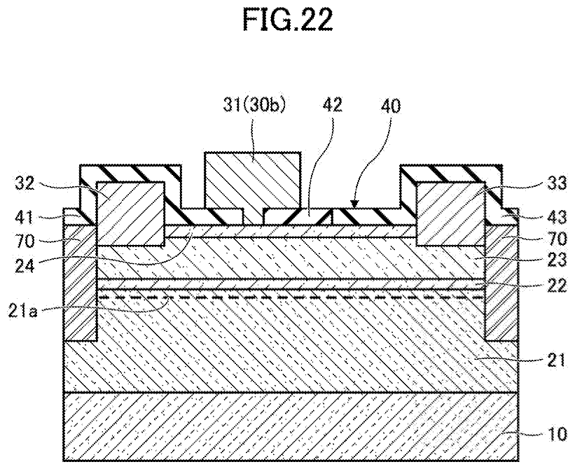

Next, as illustrated in FIG. 22, by immersing in an organic solvent or the like, the multilayer metal film 30b formed over the resist pattern 75 is removed together with the resist pattern 75 by lift-off. Thus, the gate electrode 31 is formed by the multilayer metal film 30b remaining in the opening 75a of the resist pattern 75.

By the above processes, the semiconductor device according to the present embodiment can be manufactured.

### MODIFIED EXAMPLE

Next, a manufacturing method of a modified example of the semiconductor device according to the present embodiment will be described.

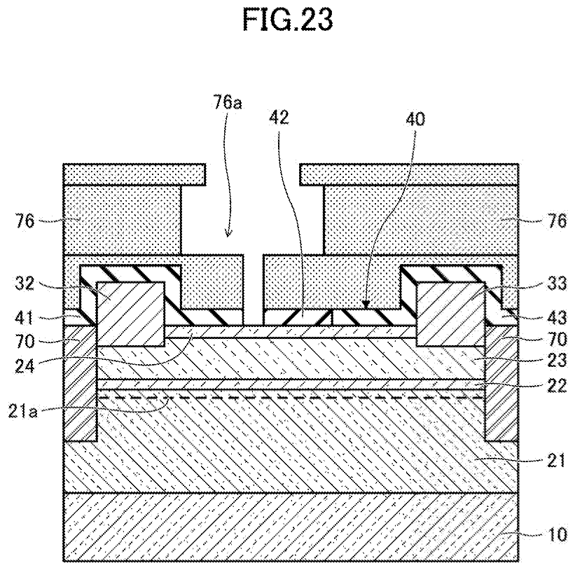

In the present modified example, from the state illustrated in FIG. 19, as illustrated in FIG. 23, a resist pattern 76 is formed to have an opening 76a in a region where a gate electrode 131 is to be formed. This resist pattern 76 is formed with three layers of electron-beam resist layers that are laminated, and has the opening 76a in the region where the gate electrode 131 is to be formed. Specifically, by repeatedly applying an electron-beam resist onto the insulative film 40, three layers of the electron-beam resist layers are formed, to which drawing and development by an electron-beam lithography device are repeatedly applied, and the opening 76a is formed in the three layers of the eleccron-beam resist layers. Thus, the resist pattern 76 having the opening 76a is formed.

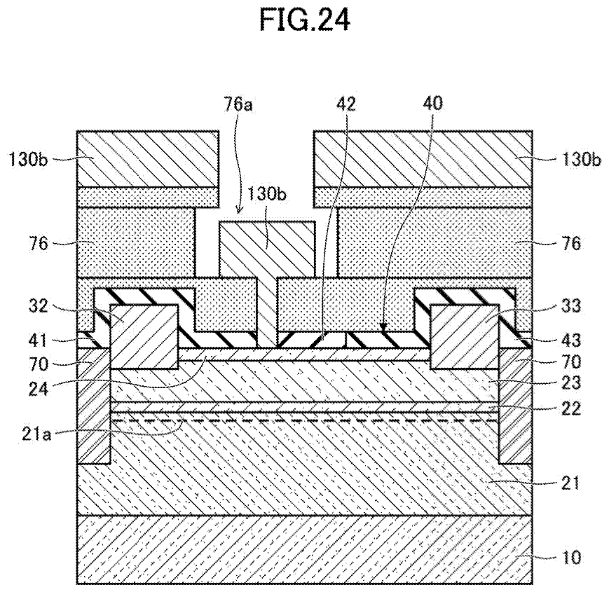

Next, as illustrated in FIG. 24, a multilayer metal film 130b to form the gate electrode 131 by vacuum deposition is deposited on the surface on which the resist pattern 76 is formed. The multilayer metal film 130b is a laminated film in which an Ni film having a film thickness of 10 nm and an Au film having a film thickness of 300 nm are laminated sequentially.

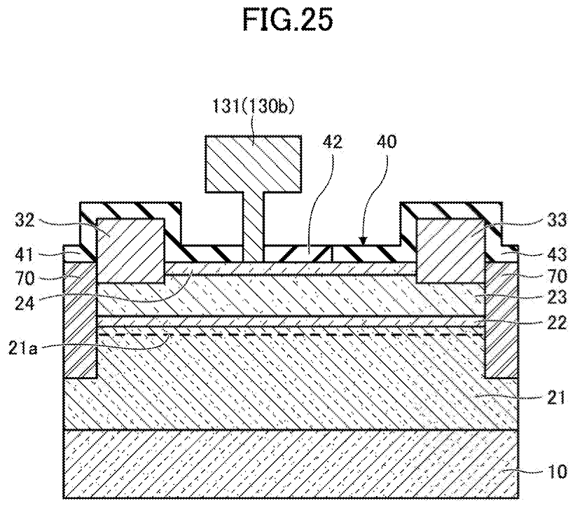

Next, as illustrated in FIG. 25, by immersing in an organic solvent or the like, the multilayer metal film 130b formed over the resist pattern 75 is removed together with the resist pattern 76 by lift-off. Thus, the gate electrode 131 is formed by the multilayer metal film 130b remaining in the region where the opening 76a of the resist pattern 76 is formed.

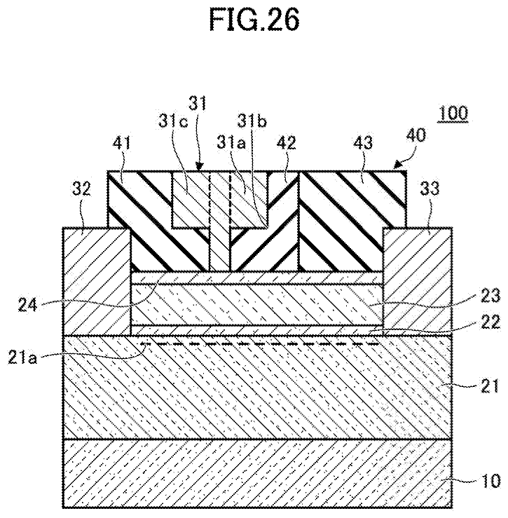

Note that as illustrated in FIG. 26, the semiconductor device according to the present embodiment may have a structure in which the source electrode 32 and the drain electrode 33 are formed over the electron transit layer 21.

### Second Embodiment

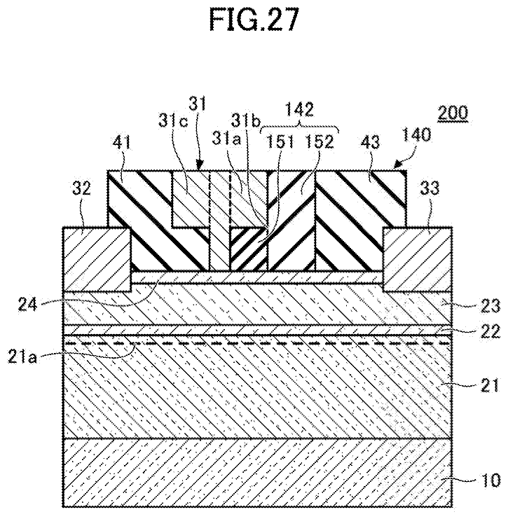

Next, a semiconductor device according to a second embodiment will be described. As illustrated in FIG. 27, a semiconductor device 200 in the present embodiment has a structure in which the density of negative charges is higher, and N/Si is greater, on the gate electrode 31-side than on the drain electrode 33-side in the second region of the insulative film.

Specifically, as illustrated in FIG. 27, the semiconductor device 200 in the present embodiment is provided with an insulative film 140 formed with a first region 41, a second region 142, a third region 43 over a cap layer 24. The second region 142 is formed with a gate-side part 151 on the gate electrode 31-side, and a drain-side part 152 on the drain electrode 33-side. Specifically, in the second region 142, the gate-side part 151 on the gate electrode 31-side is formed directly beneath the gate field plate 31a of the gate electrode 31, and the drain-side part 152 is formed on the drain electrode 33-side relative to the gate-side part 151 is to the drain electrode 33. The gate-side pare 151 of the second region 142 of the insulative film 140 is formed of silicon nitride having N/Si of 1.495, and the drain-side part 152 is formed of silicon nitride having N/Si of 1.441.

Therefore, although both the gate-side part 151 and the drain-side part 152 of the second region 142 of the insulative film 140 are formed of N-rich silicon nitride, the gate-side part 151 has a higher ratio of nitrogen and a higher concentration of negative charges than the drain-side part 152.

The silicon nitride having N/Si of approximately 1.495 that forms the gate-side part 151 of the second region 142 has a refractive index of approximately 1.85 at the wavelength of 6 33 nm, and a charge density of negative charges of 4×10¹² cm⁻² in the direction of the substrate surface. Note that the silicon nitride having N/Si of approximately 1.441 that forms the drain-side part 152 of the second region 142 has a refractive index of approximately 1.90 at the wavelength of 633 nm, and a charge density of negative charges of 4×10¹² cm⁻² in the direction of the substrate surface.

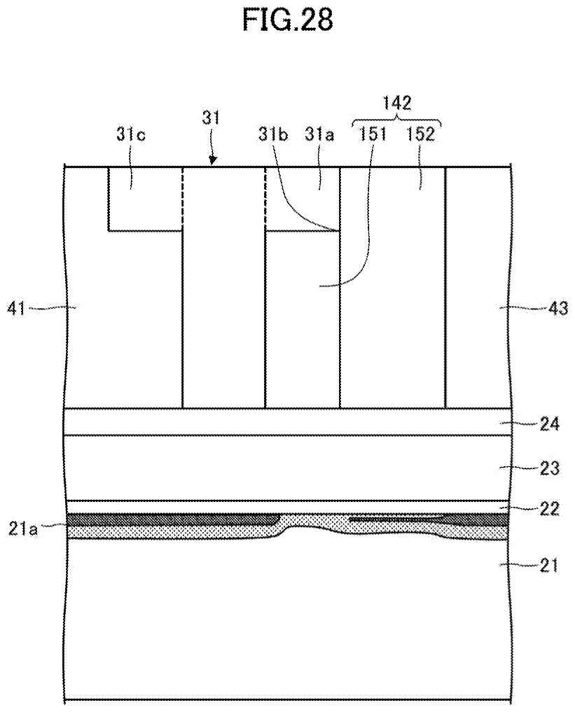

FIG. 28 illustrates a distribution of 2DEG 21a generated in the semiconductor device according to the present embodiment. As illustrated in FIG. 28, the concentration of the 2DEG 21a directly beneath the gate field plate 31a on the drain electrode 33-side of the gate electrode 31, namely, directly beneath the gate-side, part 151 of the second region, is lower than that of the drain-side part 152 on the drain electrode 33-side. Therefore, it is possible to narrow the range in which the second region 42 is formed, and thereby, to prevent the drain current from decreasing.

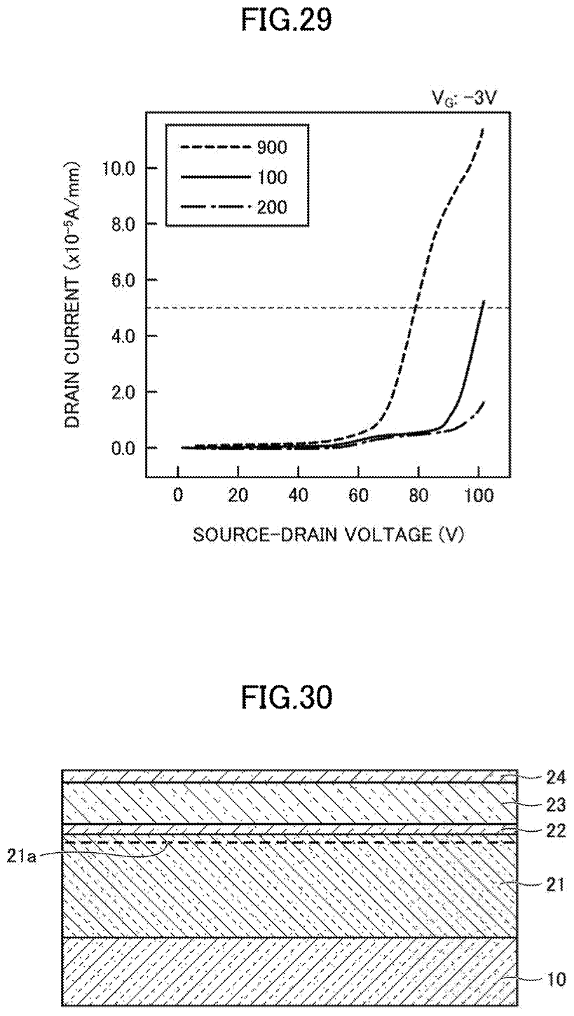

FIG. 29 illustrates a relationship between the source-drain voltage and the drain current in an off-state where −3 V is applied to the gate electrode in the semiconductor device 200 in the present embodiment illustrated in FIG. 27. Note that FIG. 29 also illustrates the relationships with respect to the semiconductor device 100 according to the first embodiment illustrated in FIG. 3, and with respect to the semiconductor device 900 illustrated in FIG. 1. As illustrated in FIG. 29, the voltage endurance of the semiconductor device 200 in the present embodiment exceeds approximately 100 V, and the voltage endurance can be higher than that of the semiconductor device 100 according to the first embodiment.

### (Manufacturing Method of Semiconductor Device

Next, a manufacturing method of the semiconductor device according to the present embodiment will be described based on FIGS. 30 to 44. Mots that in process views in the following description, for the sake of convenience, the thickness, width and the like of each layer are presented differently from those illustrated in FIG. 27 and the like; however, these do not affect the contents of the present inventive concept.

First, as illustrated in FIG. 30, a buffer layer (not illustrated), an electron transit layer 21, an intermediate layer 22, an electron supply layer 23, and a cap layer 24 are sequentially laminated and formed over a substrate 10 by epitaxial growth using MOVPE. This structure generates 2DBG 21a in the electron transit layer 21 in the vicinity of the interface between the electron transit layer 21 and the intermediate layer 22 .

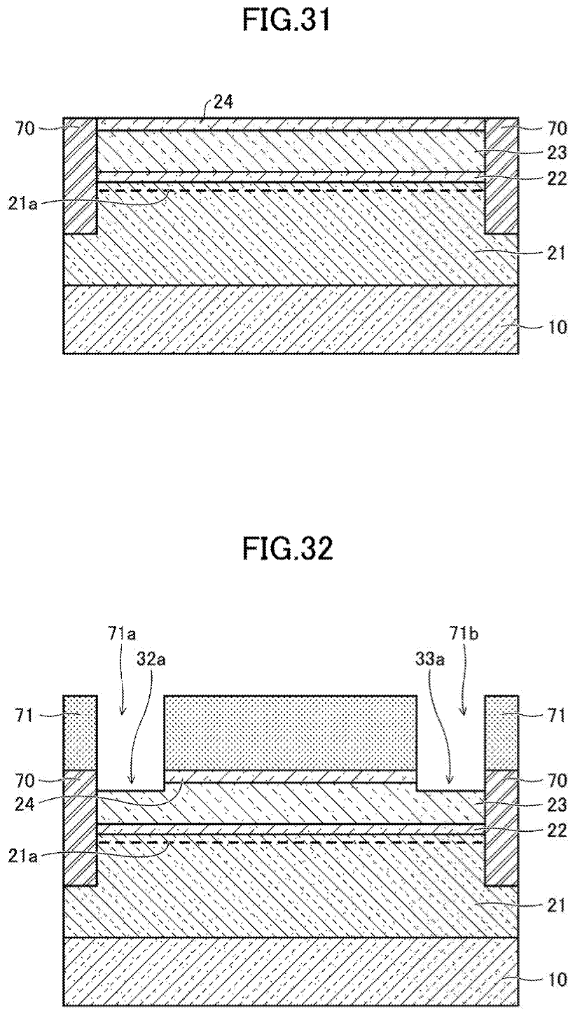

Next, as illustrated in FIG. 31, element-separating regions 70 are formed in the nitride semiconductor layers formed over the substrate 10.

Next, as illustrated in FIG. 32, a resist pattern 71 having openings 71a and 71b is formed, and then, the nitride semiconductor layers are removed in regions where a source electrode 32 and a drain electrode 33 are to be formed, to form openings 32a and 33a.

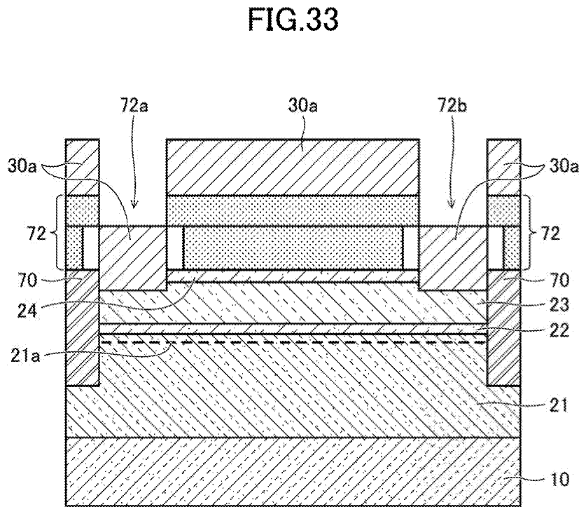

Next, as illustrated in FIG. 33, a resist pattern 72 is formed to have openings 72a and 72b to form the source electrode 32 and the drain electrode 33, and then, a multilayer metal film 30a is deposited to form the source electrode 32 and the drain electrode 33.

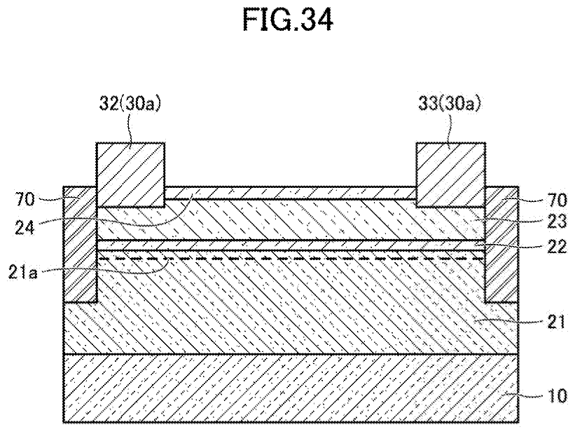

Next, as illustrated in FIG. 34, by immersing in an organic solvent or the like, the multilayer metal film 30a formed over the resist pattern 72 is removed together with the resist pattern 72 by lift-off. Thus, the source electrode 32 and the drain electrode 33 are formed by the multilayer metal film 30a remaining in the openings 72a and 72b of the resist pattern 72. After that, heat treatment is applied at a temperature of 550° C. to 650° C., to establish an ohmic contact between the nitride semiconductor layers, and the source electrode 32 and the drain electrode 33.

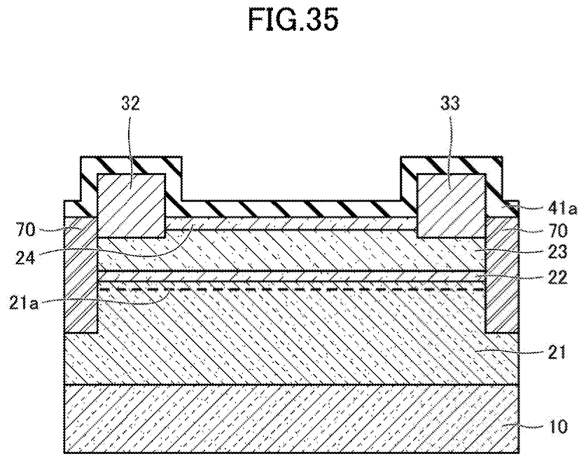

Next, as illustrated in FIG. 35, a positive-charge-containing film 41a is formed over the cap layer 24 and the like to form a first region 41 and a third region 43 of the insulative film 40.

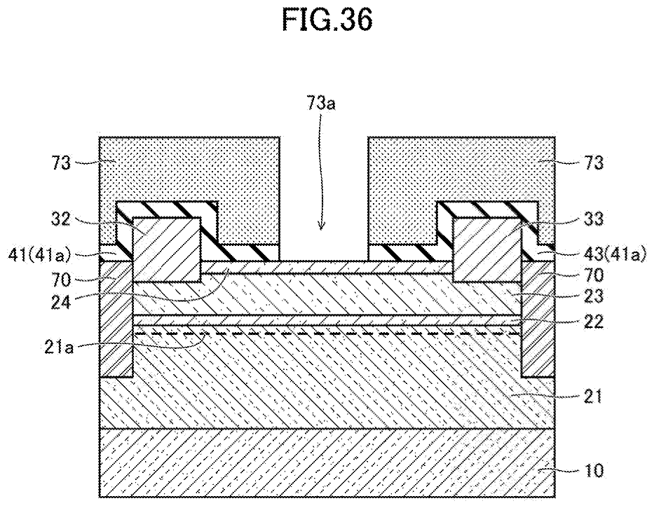

Next, as illustrated in FIG. 36, a resist pattern 73 having an opening 73a is formed over the positive-charge-containing film 41a, and then, the positive-charge-containing film 41a is removed in the opening 73a of the resist pattern 73, to expose the cap layer 24. Thus, the remaining positive-charge-containing film 41a forms the first region 41 and the third region 43 that form the insulative film 40.

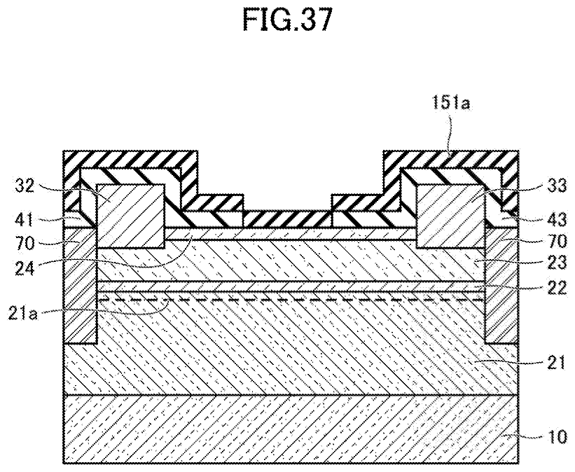

Next, as illustrated in FIG. 37, a first negative-charge-containing film 151a is formed over the cap layer 24 and the like to form a gate-side part 151 of a second region 142 of the insulative film 140. Specifically, the first negative-charge-containing film 151a is formed by depositing an SiN film having a film thickness of approximately 100 nm by plasma CVD, using si lane, ammonia, or nitrogen as the source gas. The deposit conditions when depositing the first negative-charge-containing film 151a are: a flow rate of 1.1 sccm for silane; a flow rate of 200 sccm for nitrogen; a deposition pressure of 1 Torr; and an applied power of 50 W. Thus, an N-rich first negative-charge-containing film 151a having a refractive index of 1.85 is formed.

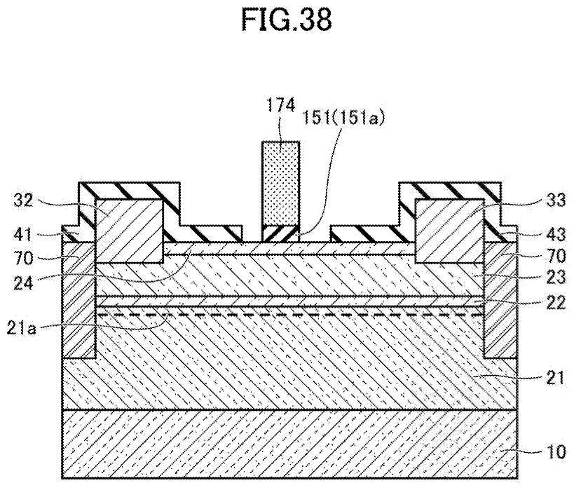

Next, as illustrated in FIG. 38, by forming a resist pattern 174 over the first negative-charge-containing film 151a, to which dry-etching such as RIE is applied, a gate-side part 151 of the second region 142 of the insulative film 140 is formed. Specifically, by applying a photoresist onto the first negative-charge-containing film 151a, which is then exposed by an exposure device and developed, the resist pattern 174 is formed over a region where the gate-side part 151 is to be formed. After that, by dry etching such as RIE, the first negative-charge-containing film 151a is removed in a region where the resist pattern 174 is not formed, and the first negative-charge-containing film 151a is formed by the remaining first negative-charge-containing film 151a.

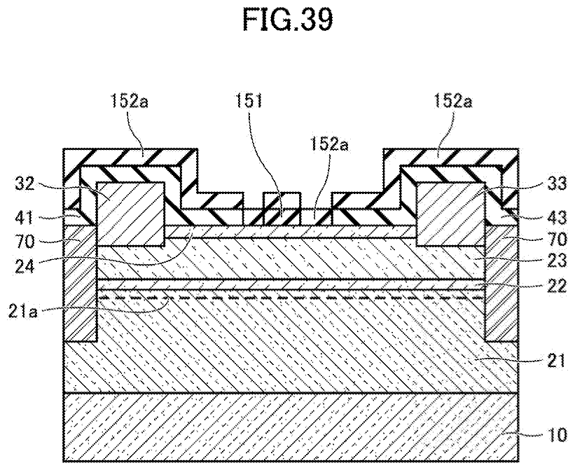

Next, as illustrated in FIG. 39, a second negative-charge-containing film 152a is formed over the cap layer 24 and the like to form a drain-side part 152 of the second region 142 of the insulative film 140. Specifically, the second negative-charge-containing film 152a is formed by depositing an SiN film having a film thickness of approximately 100 nm by plasma CVD, using silane, ammonia, or nitrogen as the source gas. The deposit conditions when depositing the second negative-charge-containing film 152a are: a flow rate of 1.4695 sccm for silane; a flow rate of 200 sccm for nitrogen; a deposition pressure of 1 Torr; and an applied power of 50 W. Thus, an N-rich second negative-charge-containing film 152a having a refractive index of 1.82 is formed. After that, heat treatment is applied at 600° C for 1 minute.

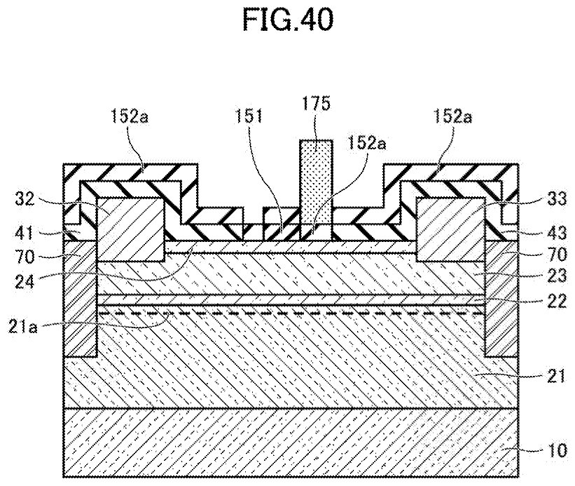

Next, as illustrated in FIG. 40, a resist pattern 175 is formed over the second negative-charge-containing film 152a in a region where the drain-side part 152 of the second region 142 of the insulative film 140 is to be formed. Specifically, by applying a photoresist onto the second negative-charge-containing film 152a, which is then exposed by an exposure device and developed, the resist pattern 175 is formed over the region where the drain-side part 152 of the second region 142 is to be formed.

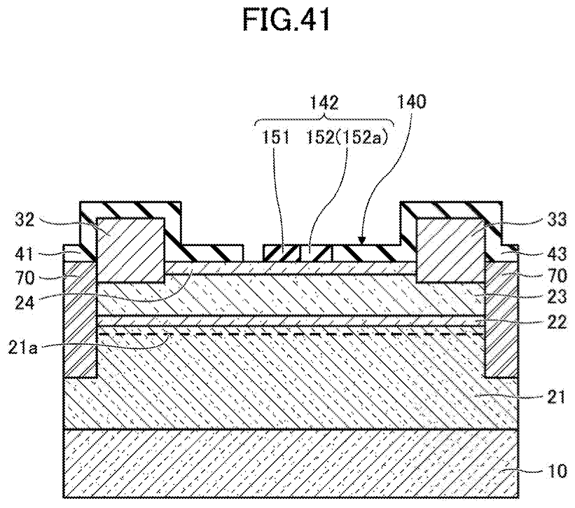

Next, as illustrated in FIG. 41, by dry etching such as RIE, the second negative-charge-containing film 152a is removed in a region where the resist pattern 175 is not formed. Thus, the remaining second negative-charge-containing film 152a forms the drain-side part 152 of the second region 142; and the gate-side part 152 and the drain-side part 152 form the second region 142. The insulative film 140 is formed with the second region 142 formed in this way, the first region 41, and the third region 43.

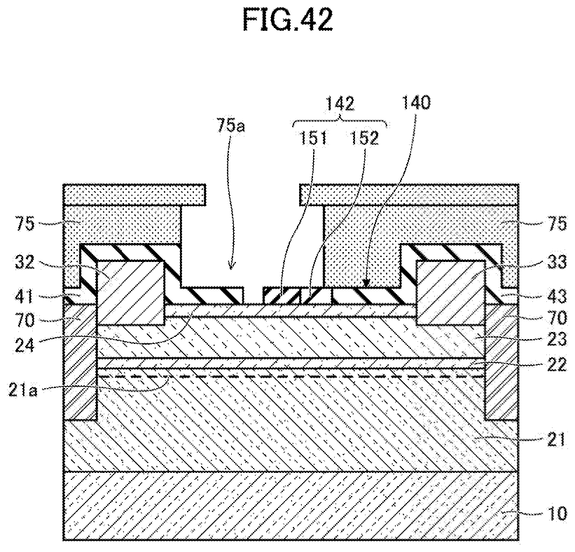

Next, as illustrated in FIG. 42, a resist pattern 75 is formed to have an opening 75a in a region where the gate electrode 31 is to be formed. This resist pattern 75 is formed with two layers of resist layers, and the opening is wider on the bottom side than on the opening side.

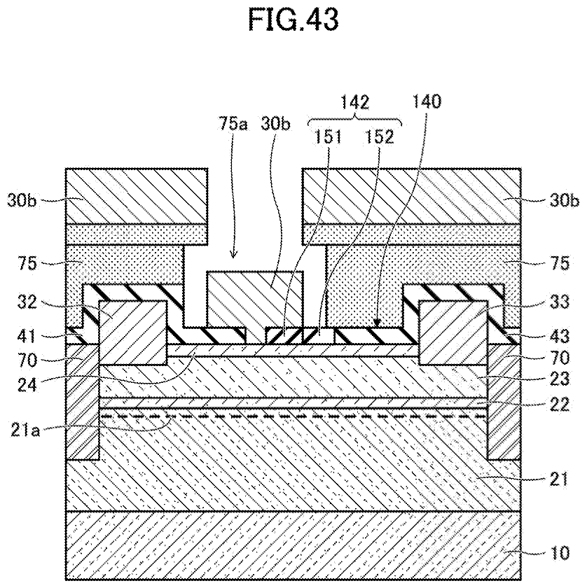

Next, as illustrated in FIG. 43, a multilayer metal film 30b to form a gate electrode 31 by vacuum deposition is deposited on the surface on which the resist pattern 75 is formed. The multilayer metal film 30b is a laminated film in which an Ni film having a film thickness of 10 nm and an Au film having a film thickness of 300 nm are laminated sequentially.

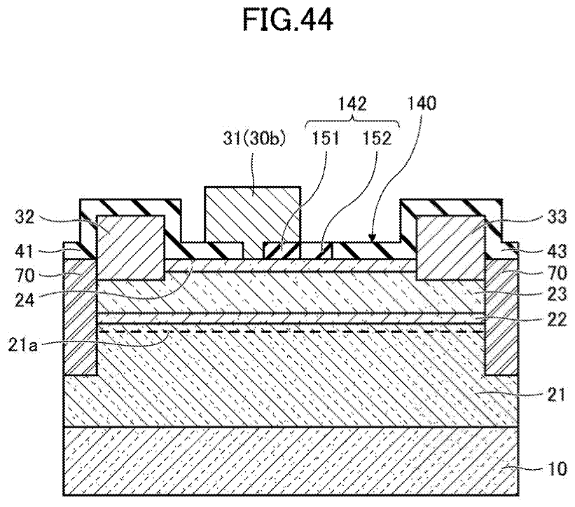

Next, as illustrated in FIG. 44, by immersing in an organic solvent or the like, the multilayer metal film 30b formed over the resist pattern 75 is removed together with the resist pattern 75 by lift-off. Thus, the gate electrode 31 is formed by the multilayer metal film 30b remaining in the opening 75a of the resist pattern 75.

By the above processes, the semiconductor device according to the present embodiment can be manufactured.

### MODIFIED EXAMPLE

Next, a manufacturing method of a modified example of the semiconductor device according to the present embodiment will be described.

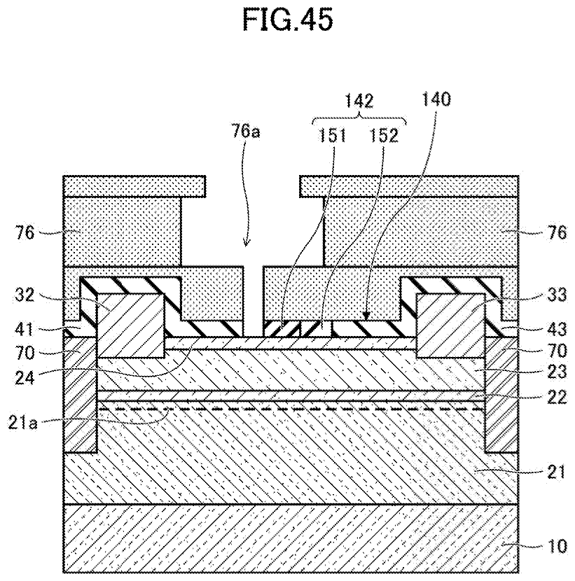

In the present modified example, from the state illustrated in FIG. 41, as illustrated in FIG. 45, a resist pattern 76 is formed to have an opening 76a in a region where a gate electrode 131 is to be formed. This resist pattern 76 is formed with three layers of electron-beam resist layers that are laminated, and has an opening 76a in the region where the gate electrode 131 is to be formed.

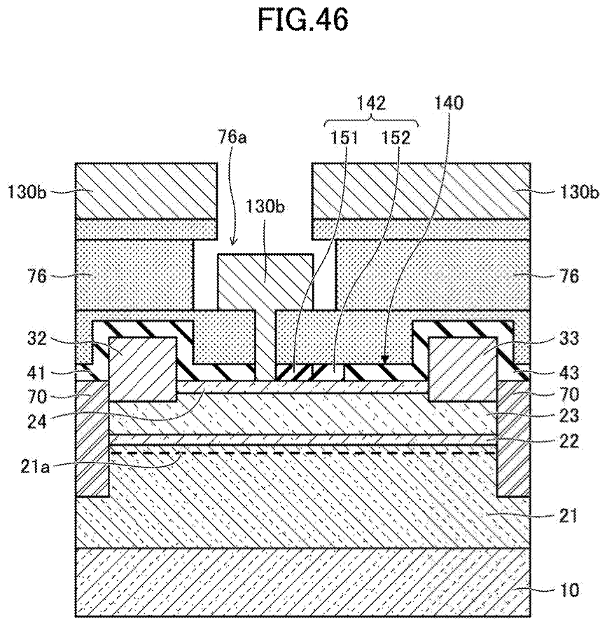

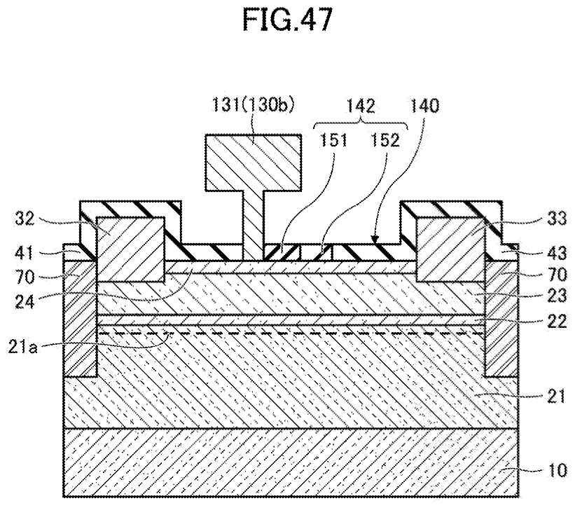

Next, as illustrated in FIG. 46, a multilayer metal film 130b to form the gate electrode 131 by vacuum deposition is deposited on the surface on which the resist pattern 76 is formed. The multilayer metal film 130b is a laminated film in which an Ni film having a film thickness of 10 nm and an Au film having a film thickness of 300 nm are laminated sequentially. Next, as illustrated in FIG. 47, by immersing in an organic solvent or the like, the multilayer metal film 130b formed over the resist pattern 76 is removed together with the resist pattern 76 by lift-off. Thus, the gate electrode 131 is formed by the multilayer metal film 130b remaining in the region where the opening 76a of the resist pattern 76 is formed.

Note that the contents other than those described above are substantially the same as in the first embodiment.

### Third Embodiment

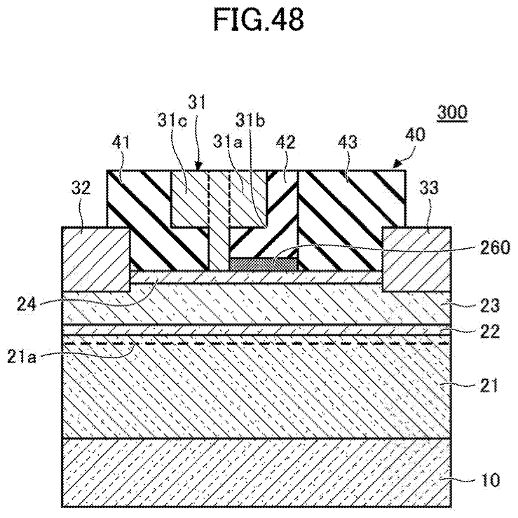

Next, a semiconductor device 300 will be described according to a third embodiment. As illustrated in FIG. 48, the semiconductor device 300 in the present embodiment has a structure in which an absorbing layer 260 is provided between a second region 42 of an insulative film 40 and a cap layer 24. The second region 42 of the insulative film 40 is formed of N-rich silicon nitride containing negative charges, where silicon nitride containing negative charges is likely to contain electron traps, and silicon nitride containing negative charges in direct contact with the nitride semiconductor layers tends to cause current collapse. Therefore, in the semiconductor device according to the present embodiment, the absorbing layer 260 is provided between the second region 42 of the insulative film 40 and the cap layer 24. The absorbing layer 260 is formed of a semiconductor or an insulator. In the present embodiment, for example, the absorbing layer 260 is formed of the same material as the silicon nitride containing positive charges that forms the first region 41 of the insulative film 40, namely, the silicon nitride having N/Si of approximately 1.063, and a refractive index of approximately 2.25 at the wavelength of 633 nm. Note that the film thickness of the absorbing layer 260 is approximately 5 nm.

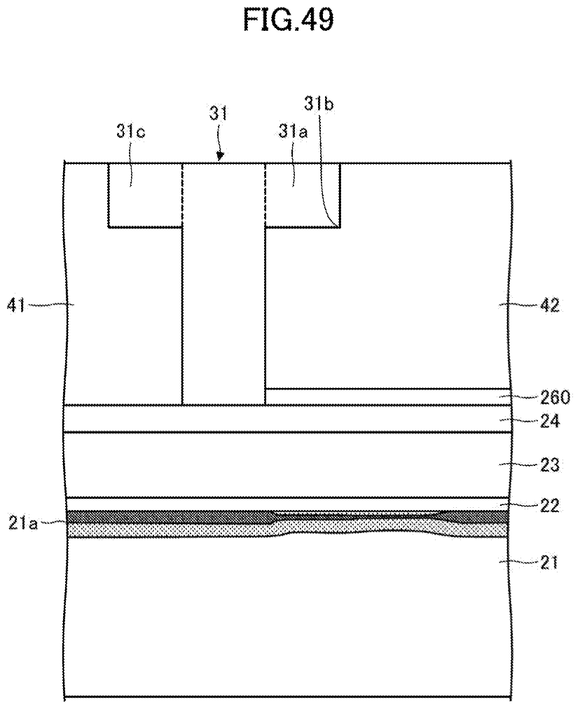

FIG. 49 illustrates a distribution of 2DEG 21a generated in the semiconductor device 300 in the present embodiment.

Although the semiconductor device 300 in the present embodiment is basically manufactured by the manufacturing method of the semiconductor device according to the first embodiment, in the process of depositing the negative-charge-containing film 42a illustrated in FIG. 17, first, a positive-charge-containing film having a film thickness of approximately 5 nm is deposited, and subsequently, a negative-charge-containing film 42a is deposited. In this way, the semiconductor devices 300 can be manufactured.

Note that the contents other than those described above are substantially the same as in the first embodiment.

### Fourth Embodiment

Next, a fourth embodiment will be described. The present embodiment relates to a semiconductor device, a power source device, and a high-frequency amplifier.

### (Semiconductor Device)

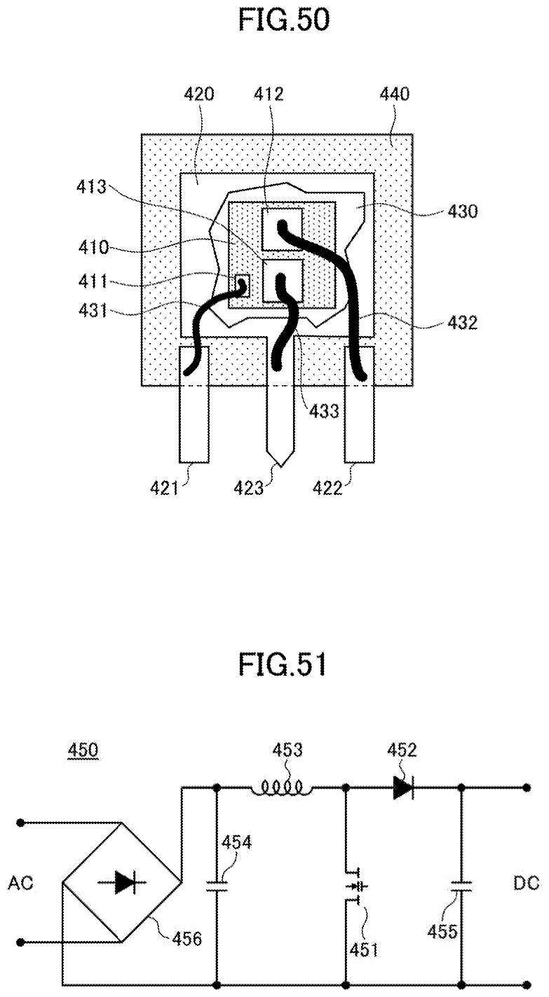

The semiconductor device according to the present embodiment is a semiconductor device according to one of the first to third embodiments that is contained in a discrete package, and the discretely packaged semiconductor device will be described based on FIG. 50. Note that FIG. 50 schematically illustrates the inside of the discretely packaged semiconductor device in which arrangement of the electrodes and the like may be different from those in the first to third embodiments.

First, a semiconductor device manufactured according to one of the first to third embodiments is cut off by dicing or the like to form a semiconductor chip 410, which is a HEMT made of GaN semiconductor materials. The semiconductor chip 410 is fixed on a lead frame 420 by a die attachment agent 430 sach as solder. Note that the semiconductor chip 410 corresponds to one of the semiconductor devices in the first to third embodiments.

Next, a gate electrode 411 is connected with a gate lead 421 by a bonding wire 431, a source electrode 412 is connected with a source lead 422 by a bonding wire 432, and a drain electrode 413 is connected with a drain lead 423 by a bonding wire 433. Note that the bonding wires 431, 432, and 433 are formed of a metal material such as Al. Also, in the present embodiment, the gate electrode 411 is a type of gate electrode pad, which is connected with the gate electrode 31 of the semiconductor device according to one of the first to third embodiments. Also, the source electrode 412 is a type of source electrode pad, which is connected with the source electrode 32 of the semiconductor device according to one of the first to third embodiments. Also, the drain electrode 413 is a type of drain electrode pad, which is connected with the drain electrode 33 of the semiconductor device according to one of the first to third embodiments.

Next, resin sealing is performed by a transfer molding method using a mold resin 440. In this way, the HEMT made of GaN semiconductor materials can be manufactured as the discretely packaged semiconductor device.

### (PFC Circuit, Power Source Device and High-Frequency Amplifier)

Next, a PFC circuit, a power source device and a high-frequency amplifier will be described according to the present embodiment. Each of the PFC circuit, the power source device, and the high-frequency amplifier in the present embodiment uses one or more of the semiconductor devices in the first to third embodiments.

### (PFC Circuit)

Next, the PPC (Power Factor Correction) circuit will be described according to the present embodiment. The PFC circuit in the present embodiment includes a semiconductor device according to one of the first to third embodiments.

The PFC circuit 450 in the present embodiment will be described based on FIG. 51. The PPC circuit: 4 50 in the present embodiment includes a switching element (transistor) 451, a diode 452, a choke coil 453, capacitors 454 and 455, a diode bridge 456, and an AC power supply (not illustrated). The switching element 451 includes a HEMT as a semiconductor device according to one of the first to third embodiments.

The drain electrode of the switching element 451, the anode terminal of the diode 452, and one of the terminals of the choke coil 453 are connected with each other in the PPC circuit 450. Also, the source electrode of the switching element 451, one of the terminals of the capacitor 454, and one of the terminals of the capacitor 455 are connected with each other, and the other terminal of the capacitor 454 is connected with the other terminal of the choke coil 453. The other terminal of the capacitor 455 is connected with the cathode terminal of the diode 452, and the AC power supply (not illustrated) is connected with both terminals of the capacitor 454 via the diode bridge 456. This PFC circuit 450 outputs a direct current (DC) from both terminals of the capacitor 455.

### (Power Source Device)

Next, the power source device will be described according to the present embodiment. The power source device according to the present embodiment includes HEMTs as semiconductor devices according to one of the first to third embodiments.

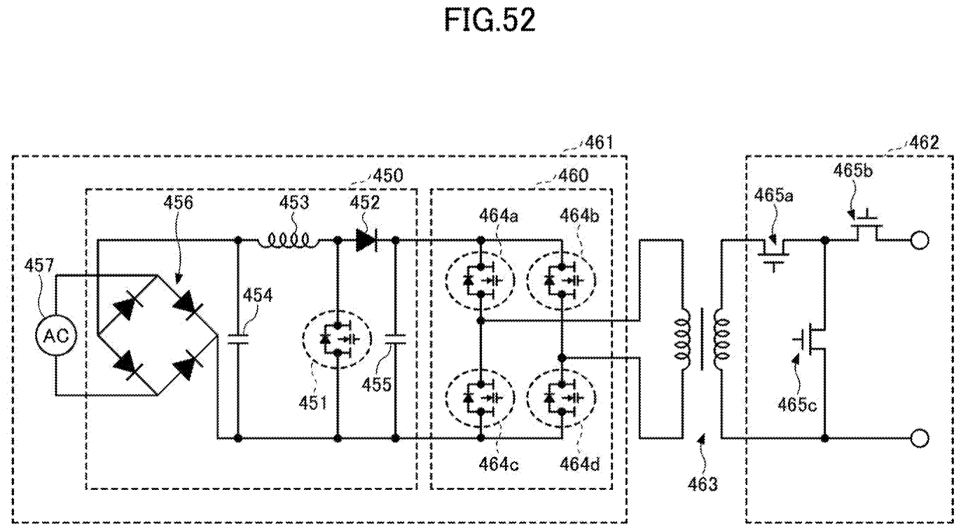

First, the power source device according to the present embodiment will be described based on FIG. 52. The power source device according to the present embodiment has a structure that includes a PPC circuit 450 in the present embodiment described above.

The power source device according to the present embodiment includes a high-voltage primary circuit 461, a low-voltage secondary circuit 462, and a transformer 463 disposed between the primary circuit 461 and the secondary circuit 462.

The primary circuit 461 includes the PPC circuit 450, and an inverter circuit, for example, a full-bridge inverter circuit 460 connected with terminals of the capacitor 455 in the PPC circuit 450. The full-bridge inverter circuit 460 includes multiple (four in this example) switching elements 464a, 464b, 464c, and 464d. Also, the secondary circuit 462 includes multiple (three in this example) switching elements 465a, 465b, and 465c. Note that the diode bridge 456 is connected with an AC power supply 457.

In the PFC circuit 450 of the primary circuit 461 in the present embodiment, the switching element 451 includes a HEM7, or a semiconductor device according to one of the first to third embodiments. Further, the switching elements 464a, 464b, 464c, and 464d in the full-bridge inverter circuit 460 include HEMTs, respectively, that are semiconductor devices according to the first to third embodiment. On the other hand, the switching elements 465a, 465b, and 465c in the secondary circuit 462 use usual MISFBTs (metal insulator semiconductor field effect transistor) or the like formed of silicon, respectively.

### (High-Frequency Amplifier)

Next, the high-frequency amplifier in the present embodiment will be described. The high-frequency amplifier 430 in the present embodiment has a structure including a HEMT as a semiconductor device according to the first or second embodiment.

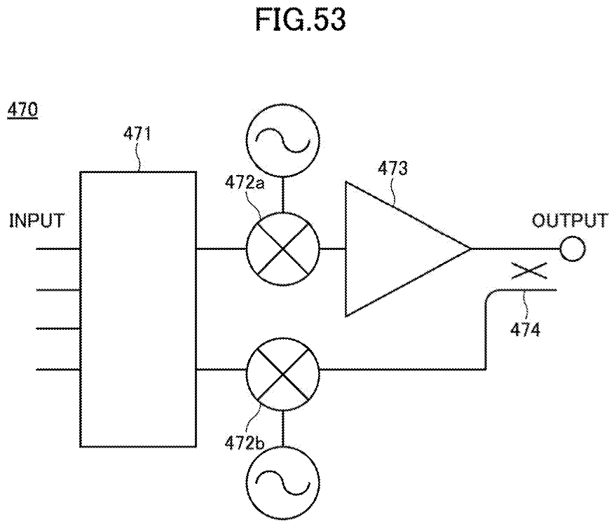

The high-frequency amplifier in the present embodiment will be described based on FIG. 53. This high-frequency amplifier 470 includes a digital predistortion circuit 471, mixers 472a and 472b, a power amplifier 473, and a directional coupler 474.

The digital predistortion circuit 471 compensates for non-linear distortion of an input signal. The mixer 472a mixes the input signal having non-linear distortion compensated, with an alternating current signal. The power amplifier 473 amplifies the input signal having been mixed with the alternating current signal, and includes a HEMT, or a semiconductor device according to one of the first to third embodiments. The directional coupler 474 monitors the input signal and an output signal. In the circuit illustrated in FIG. 53, by turning on/off a switch, for example, it is possible to mix the output signal with an alternating current signal by using the mixer 472b, and to transmit the mixed signal to the digital predistortion circuit 471.

As above, the embodiments of the present, invention have been described in detail; it should be noted that the various modifications and alterations can be made within the scope of the present inventive concept described in the claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a first semiconductor layer formed of a nitride semiconductor over a substrate;
a second semiconductor layer formed of a nitride semiconductor over the first semiconductor layer;
a gate electrode formed over the second semiconductor layer;
a source electrode and a drain electrode formed over the first semiconductor layer or the second semiconductor layer;
a first region of an insulative film that is formed between the gate electrode and the source electrode over the second semiconductor layer, and contains positive charges; arid
a second region of the insulative film that is formed between the gate electrode and the drain electrode over the second semiconductor layer, and contains negative charges.

2. The semiconductor device as claimed in claim 1, wherein the second region is formed between the gate electrode and the drain electrode on a gate electrode-side, and in the insulative film, a third region containing positive charges is formed between the second region and the drain electrode.

3. The semiconductor device as claimed in claim 1, wherein the gate electrode includes a gate field plate formed over the insulative film, and
wherein the second region is formed in a region that includes a part directly beneath a drain electrode-side of the gate field plate.

4. The semiconductor device as claimed in claim 1, wherein in the second region, a part on a gate electrode-side has a higher density of negative charges than a part on a drain electrode-side.

5. The semiconductor device as claimed in claim 4, wherein the gate electrode includes a gate field plate formed over the insulative film, and
wherein the part on the gate electrode-side is formed directly beneath the gate field plate on the drain electrode-side.

6. The semiconductor device as claimed in claim 1, wherein an absorbing layer formed of a semiconductor or insulator is provided between the second region of the insulative film and the second semiconductor layer.

7. The semiconductor device as claimed in claim 6, wherein the absorbing layer is formed of an insulative film containing positive charges.

8. The semiconductor device as claimed in claim 1, wherein the first region and the second region are formed of a same material, and contain charges of polarities opposite to each other.

9. The semiconductor device as claimed in claim 1, wherein the insulative film is formed of a material that contains one of silicon nitride, aluminum nitride, silicon oxide, aluminum oxide, hafnium oxide, and magnesium oxide.

10. The semiconductor device as claimed in claim 9, wherein the first region is in a state of containing less nitrogen or oxygen than in a stoichiometric state, and
wherein the second region is in a state of containing more nitrogen or oxygen than in the stoichiometric state.

11. The semiconductor device as claimed in claim 1, wherein the insulative film is formed of a material containing silicon nitride,
wherein the first region is in a state of containing less nitrogen than in Si₃N₄ in the stoichiometric state, and
wherein the second region is in a state of
containing more nitrogen than in Si₃N₄.

12. The semiconductor device as claimed in claim 1, wherein the first region has a higher refractive index at a wavelength of 633 nm than the second region.

13. The semiconductor device as claimed in claim 1, wherein the first semiconductor layer is formed of a material including GaN, and wherein the second semiconductor layer is formed of a material including one of AlGaN, AlN, InAlN, and InGaAlN.

14. The semiconductor device as claimed in claim 13, wherein an intermediate layer is formed of a material containing AlN between the first semiconductor layer and second semiconductor layer.

15. The semiconductor device as claimed in claim 14, wherein a cap layer is formed of a material containing GaN over the second semiconductor layer, and
wherein the gate electrode and the insulative film are formed over the cap layer.

16. A manufacturing method of a semiconductor device, the method comprising:
forming a first semiconductor layer made of a nitride semiconductor over a substrate;
forming a second semiconductor layer made of a nitride semiconductor over the first semiconductor layer;
forming a source electrode and a drain electrode over the first semiconductor or the second semiconductor layer;
forming an insulative film over the second semiconductor layer; and
forming a gate electrode over the second semiconductor layer,
wherein the forming of the insulative film includes
forming a first region of the insulative film containing positive charges, on a source electrode-side of the gate electrode, and
forming a second region of the insulative film containing negative charges, on a drain electrode-side of the gate electrode.

17. The manufacturing method of the semiconductor device as claimed in claim 16, wherein the insulative film is formed by plasma CVD or sputtering.

18. The manufacturing method of the semiconductor device as claimed in claim 16, wherein in the forming of the insulative film, subsequent to formation of the first region and the second region, heat treatment is performed at a temperature higher than or equal to 600° C.

19. A power source device comprising: the semiconductor device as claimed in claim 1.

20. An amplifier comprising:
the semiconductor device as claimed in claim 1.
